(19) United States
(12) Patent Application Publication
(10) Pub. No.: US 2024/0055305 A1
(43) Pub. Date: Feb. 15, 2024

(54) SACRIFICIAL LAYER FOR SUBSTRATE ANALYSIS

(71) Applicant: Intel Corporation, Santa Clara, CA (US)

(72) Inventors: Santosh TRIPATHI, Portland, OR (US); Tuyen TRAN, Portland, OR (US)

(21) Appl. No.: 17/887,273

(22) Filed: Aug. 12, 2022

(51) Int. Cl. H01L 21/66; H01L 21/02

(52) U.S. Cl. CPC H01L 22/22; H01L 22/12; H01L 21/02282; H01L 21/02318

(57) ABSTRACT

Embodiments described herein may be related to apparatuses, processes, systems, and/or techniques for analyzing a wafer for defects using cross-section analysis by applying a sacrificial layer on a surface of the wafer prior to forming a cavity into the wafer for analysis. In embodiments, an epoxy material may be placed into the cavity after analysis, and a capping layer placed on top of the epoxy material. The sacrificial layer, which may contain dislodged particles or debris from the formation of the cavity on its surface, is then removed, providing a clean surface on the wafer. The wafer may then be reintroduced into the manufacturing line for further processing. Other embodiments may be described and/or claimed.

### FIELD

Embodiments of the present disclosure generally relate to the field of semiconductor manufacturing, and in particular to testing for defects on a wafer.

### BACKGROUND

Continued growth in virtual machines, cloud computing, and portable devices will continue to increase the demand for high density transistors within chips and packages. In addition, there will be an increased need for high quality components with an improved efficiency in identifying device defects on a package substrate or on a wafer.

### BRIEF DESCRIPTION OF THE DRAWINGS

FIG. 1 shows elements of a legacy process that uses cross-section analysis for checking for defects within a wafer.

FIGS. 2A-2H show cross section side views and a top-down view of stages in a manufacturing process for checking for defects within a wafer that includes a sacrificial layer and an epoxy fill, in accordance with various embodiments.

FIGS. 3A-3B show cross section views of alternative stages in a manufacturing process for checking a region of interest using a conformal sacrificial layer, in accordance with various embodiments

FIGS. 4A-4F show cross section side views of stages in a manufacturing process for checking for defects within a wafer with an uneven surface, in accordance with various embodiments.

FIG. 5 illustrates a process for performing a cross-section analysis of a substrate, in accordance with various embodiments.

FIG. 6 illustrates a computing device in accordance with one implementation of the invention.

FIG. 7 illustrates an interposer that includes one or more embodiments of the invention.

### DETAILED DESCRIPTION

Embodiments described herein may be related to apparatuses, processes, systems, and/or techniques for analyzing a wafer for defects using cross-section analysis during a stage in the manufacturing process. Cross-section analysis may be performed by forming a cavity, which may be referred to as a void, into the wafer and performing an analysis on the material removed or an edge of cavity, and then returning the analyzed wafer to the manufacturing line for further processing. In embodiments, a wafer may also refer to a package substrate, a stack of wafers bonded together, or a wafer with one or more stack of dies attached to it, and the like. In addition, cross-section analysis may be only one of several use case of forming a cavity, filling it up and sending the wafer for further processing. Examples may include, but are not limited to, disabling part of the functionality of the system or improving thermal performance.

Embodiments may involve applying a layer, which may be referred to as a sacrificial layer, on top of the wafer prior to removing material to form the cavity. In embodiments, after the material has been removed, the cavity may be partially filled using an epoxy or some other material. A cap may then be formed by covering the cavity, and/or the immediate vicinity of the cavity, with a dielectric material or some other material compatible with a current manufacturing stage of wafer processing. As a result, the cavity may be substantially filled.

In embodiments, when the sacrificial layer is removed, any debris deposited on the surface of the wafer when the cavity is formed will also be removed. The resulting top layer of the wafer will be free from debris and ready for further processing on the manufacturing line.

Cross-section image and analysis may provide valuable insights into the manufacturing process and may be used to drive decisions during all phases of fabrication process. By providing direct information on the defects and process variations, cross-section analysis can expedite root-cause identification of issues as well as high fidelity monitoring of the process line.

Cross-section analysis techniques may also be used to calibrate other metrology techniques, for example optical critical dimension measurements. In legacy implementations, cross-section defect analysis techniques that involve forming a cavity into a wafer result in damage to the entire wafer, which makes the wafer unsuitable for further manufacturing stages. This damage results from debris being deposited on the surface of the wafer as the cavity is formed, as well as the resulting uneven topography of the surface of the wafer due to the resulting cavity. As a result, the entire wafer has to be discarded, and not used for downstream processing. In addition, during the legacy manufacturing process, the manufacturing line is slowed down which reduces information turns, the rate at which the learnings can be extracted from the process line. This is because some wafers are processed only through a portion of the manufacturing line, where the wafers chosen for defect analysis will be pulled from the line and scrapped.

In addition, with these legacy implementations, due to wafer loss there may be a limit on the number of wafers that may be practically used in defect analysis. This may result in lost collection of data that may have otherwise provided insight on the resolution of wafer manufacturing or design issues. It may also create an informational hole, which is a lack of data on the wafer for rest of the processing flow beyond at which it was pulled from the processing line for analysis. As a result, this limit insights during data analysis that could have been extracted from the otherwise discarded set of wafers.

Embodiments described herein facilitate the reduction of the number of wafers that need to be started in order to receive the same amount of defect information. As a result, information turn is improved, and development cost may be reduced. Embodiments may also facilitate advanced data analysis by removing the information hole that is currently created by having to pull the wafers from the manufacturing line for cross-section analysis. In addition, embodiments may facilitate data collection by a process development and monitoring teams without having to compromise their data collection based on a limited number of wafers that may be available.

In embodiments, a single wafer may be subjected to cross-section analysis during multiple stages on the manufacturing line. In addition, these wafers subjected to cross-section analysis may be used in production units, provided the cross-section analysis is applied in a non-active area of a die on a wafer that may be left unused, for example, due to tiling constraints of different circuitries within a die. In some embodiments, the cross-section analysis may disable some functionality of a die resulting from the wafer, yet the die could be functional as a lower bin part.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

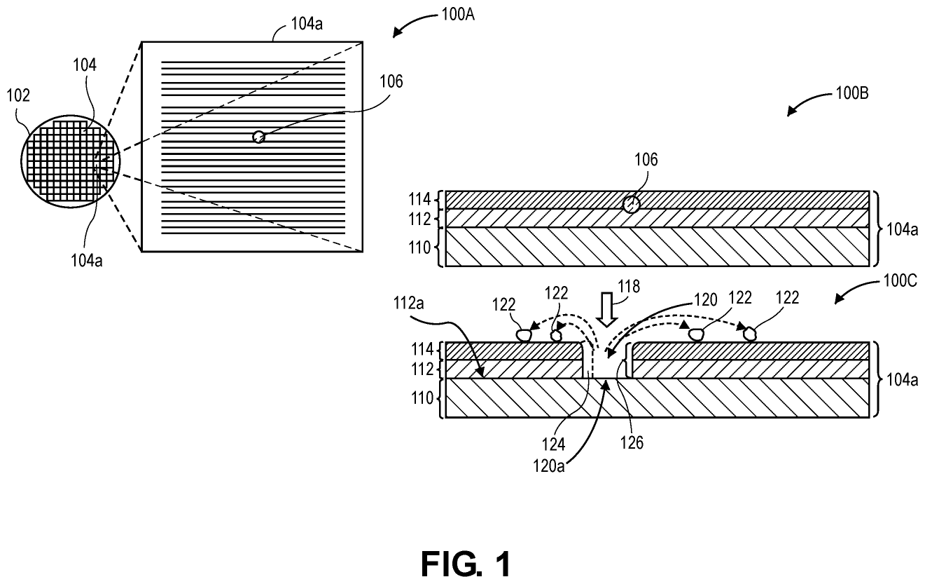

FIG. 1 shows elements of a legacy process that uses cross-section analysis for checking for defects within a wafer. Diagram 100A shows a top-down view of a wafer 102 that includes a plurality of wafer portions 104 on the wafer 102. In embodiments, each of the plurality of wafer portions 104 may correspond to a die, or to some other structure that is part of the wafer 102. Wafer portion 104a shows a top-down expanded view of a portion of the wafer 102.

Wafer portion 104a may include an indication of a possible defect 106. In embodiments, the indication of the possible defect 106 may be a region of interest for some other reason, for example, a predefined location for monitoring. The indication of the possible defect 106 may be identified by using a number of techniques that may include optical scanning or electrical testing. For optical scanning, a scan may be performed of images of a top of wafer 102 to identify the indication of the possible defect 106, its location, and one or more potential defects to which it may be related.

In other implementations, a partial or full device, for example within the wafer portion 104a, on the wafer 102, may electrically connected to a tester (not shown) and have electrical signals and/or power applied. Based on the resulting electrical data from the test, the indication of the possible defect 106, its location, and one or more potential defects to which it may be related may also be identified. Once the indication of the possible defect 106 is identified, an assessment is made whether a cross-section analysis should be made proximate to that location.

Diagram 100B shows a cross section side view of the wafer portion 104a that includes a first layer 110, a second layer 112, and a third layer 114. In this example, the indication of the possible defect or region of interest 106 is in the area of the second layer 112 and the third layer 114. Diagram 100C shows an example implementation if a decision to proceed with a cross-section analysis has been made. For example, a cavity 120 may be formed as material of the wafer portion 104a proximate to the indication of the possible defect 106 is removed and analyzed. In some implementations, the removal and analysis process may be repeated, which may increase the size of cavity 120. As shown, the cavity 120 may extend through third layer 114 and the second layer 112. In embodiments, the cavity 120 may be few microns to few millimeter across and few microns to few millimeters in depth. Also, depending upon the techniques used to form the cavity 120, a bottom of the cavity 120a may not be coplanar with a bottom surface 112a of the second layer 112.

The cavity 120 may be formed using a number of different techniques. In one example, a focused ion beam 118 may shoot large molecules at the wafer portion 104a at a very high velocity and dislodge particles of material that may be in second layer 112 or third layer 114. These dislodged particles 122 may also be referred to as debris and may be at least partially scattered on the top of the third layer 114. In some implementations, the dislodged particles 122 may be analyzed using a time-of-flight (TOF) secondary ion mass spectrometer (SIMS) analysis. TOF SIMS data may be used to identify defects within the area of the wafer portion 104a.

In other implementations, a milling machine (not shown) may be used to create a thin layer of cross-section material 124, which may be referred to as a lamella. The cross-section material 124 may then be removed and subsequently analyzed using a transmission electron microscope (TEM). In other implementations, images of an exposed vertical profile 126 along the side of the cavity 120 may be captured and analyzed using focused ion beam techniques in conjunction with a scanning electron microscope (SEM).

In each of these implementations, in addition to creating cavity 120, the process of moving material out of the second layer 112 and the third layer 114 for analysis when creating cavity 120 causes dislodged particles 122 to fly off and land on the top of the third layer 114. As a result, wafers that are removed from the manufacturing line analyzed using these legacy techniques cannot be returned to the manufacturing line for further processing, and must be discarded. This is due to at least two factors. First, the dislodged particles 122 that land on the surface of the wafer 102 cannot be adequately removed and will negatively impact future stages of the wafer 102 manufacturing process. Second, the cavity 120 created within the surface of the wafer 102 negatively impacts downstream processing, for example, by resulting in an inability to print accurately during lithographic process and causes a non-uniform polish rate in the areas near the cavity during planarization process when subsequent layers (not shown) may be added on top of the wafer 102 during further processing.

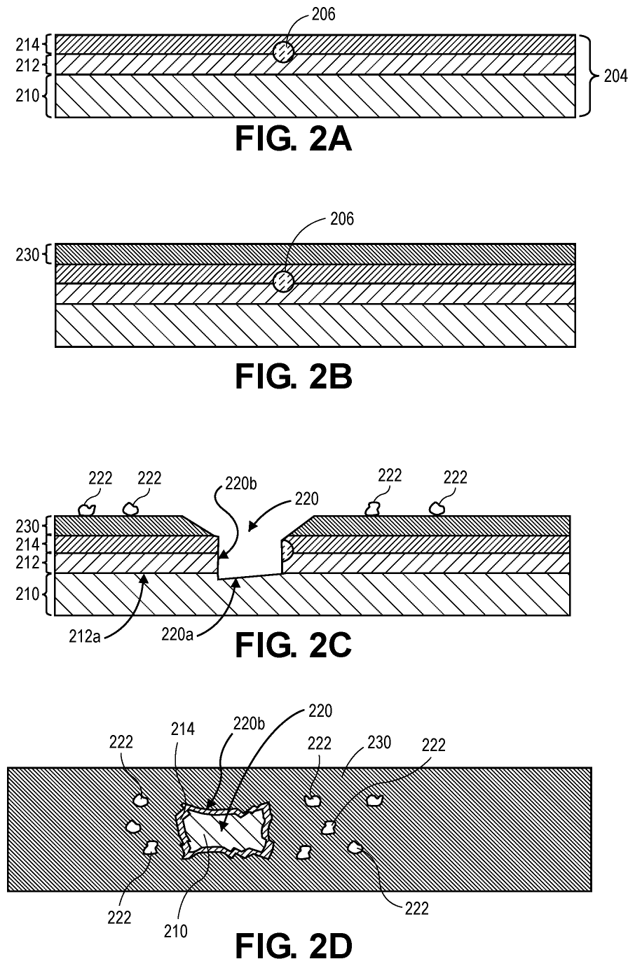

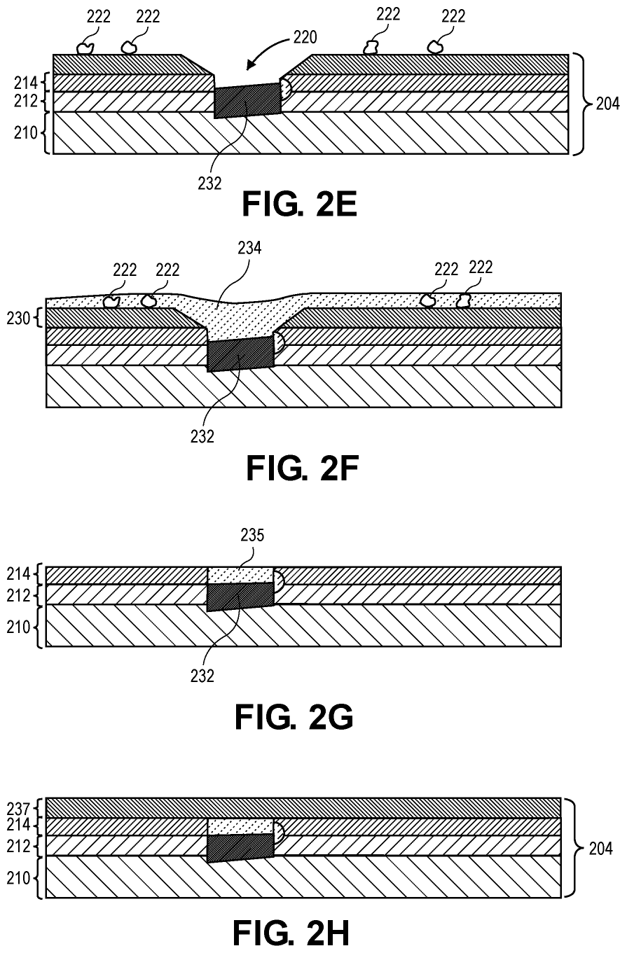

FIGS. 2A-2H show cross section side views or top-down views of stages in a manufacturing process for checking for defects within a wafer that includes a sacrificial layer and an epoxy fill, in accordance with various embodiments. FIG. 2A shows a cross section side view of a stage in the manufacturing process where a wafer portion 204, which may be similar to wafer portions 104 or wafer portion 104a of wafer 102 of FIG. 1, is provided.

Wafer portion 204 may include a first layer 210, a second layer 212, and a third layer 214. In embodiments, the first layer 210 may be a silicon layer. In embodiments, the second layer 212 and/or the third layer 214 may include electrical circuitry or other electrical components (not shown). In embodiments, the first layer 210, the second layer 212, and the third layer 214 may include sublayers. In embodiments, an indication of a possible defect 206, which may be similar to an indication of a possible defect 106 of FIG. 1, may have been identified using techniques described with respect to FIG. 1, and a decision to perform a cross section analysis on the wafer portion 204 has been made.

In embodiments, the wafer portion 204, which may also be referred to as a substrate, may also be a selected one or more of: a portion of one or more bonded wafers, a wafer that may have one or more individual dies attach to a side of the wafer, a package substrate, or a packaged unit.

FIG. 2B shows a cross section side view of a stage in the manufacturing process where a sacrificial layer 230 is placed on top of the third layer 214. In embodiments, material and thickness of the sacrificial layer 230 may be selected based on the technique used to form the cavity and sample type for example single wafer, bonded wafers, package substrate, among others. In embodiments, focused ion beam milling and electron-beam induced etching could use dielectric materials with few tens of nanometers thickness, in contrast, a lithography and etch combination could need stack of multiple layers. In some embodiments, the cavity formation begins by aligning the wafer to establish the location of the possible defect 206, which may otherwise be a region of interest. In embodiments, a material and thickness of the sacrificial layer 230 may be selected that does not interfere with the alignment accuracy. Further, the sacrificial layer 230 should be thick enough to protect the active surface from the debris, such as dislodged particles 222 of FIG. 2C.

FIG. 2C shows a cross section side view of a stage in the manufacturing process where a cavity 220, which may be similar to cavity 120 of FIG. 1, is formed within the sacrificial layer 230, the third layer 214, and the second layer 212. In some embodiments, the cavity 220 may partially extend into the first layer 210. In embodiments, the cavity 220 may be formed using the techniques described with respect to FIG. 1. In embodiments, a bottom surface 220a of the cavity 220, which may be similar to bottom surface 120a of the cavity 120 of FIG. 1, may not be coplanar with a bottom surface 212a of the second layer 212. In embodiments, one or more of the sidewalls 220b of the cavity 220 may be substantially vertical and may be substantially perpendicular to a plane of the second layer 212.

Dislodged particles 222, which may be similar to dislodged particles 122 of FIG. 1, which were produced when the cavity 220 was formed, may be on the surface of the sacrificial layer 230. Note that none of the dislodged particles 222 are on the surface of the third layer 214, where the surface of the third layer 214 is shielded by the sacrificial layer 230. In embodiments, at this stage the wafer portion 204 with the cavity 220 may be subjected to the various cross section analysis tests as described with respect to FIG. 1.

FIG. 2D shows a top-down view of the stage in the manufacturing process associated with FIG. 2C, where the cavity 220 is formed through the sacrificial layer 230, the third layer 214, and exposing the first layer 210. In embodiments, the cavity 220 may be roughly rectangular shape; however, in other embodiments, the cavity may have some other irregular shape. In embodiments, the sidewalls of the cavity 220 may be jagged and/or rough with respect to a plane of the sacrificial layer 230. In embodiments, dislodged particles 222 may be on a surface of the sacrificial layer 230.

FIG. 2E shows a cross section side view of a stage in the manufacturing process where a volume of material 232 is placed and/or inserted within the cavity 220. In embodiments, the material 232 may include an epoxy material that may be applied and reflowed into the cavity 220. In embodiments, the material 232 may be referred to as a filling material. In embodiments, the material 232 may be surrounded by portions of the first layer 210, portions of the second layer 212, and/or portions of the third layer 214. In embodiments, the material 232 may be a liquid mold material.

In embodiments, the material 232 may include silicon dioxide and/or other dielectric materials. In embodiments, the material 232 may include material that is not found in second layer 212 or third layer 214. In other embodiments, the material 232 may include compounds that match coefficient of thermal expansion (CTE) of the material 232 with the components that are in the wafer portion 204, in particular with respect to the first layer 210, second layer 212 and/or third layer 214. In other embodiments, the material 232 may include compounds that match the Young's modulus of the material 232 with the components that are in the wafer portion 204.

FIG. 2F shows a cross section side view of a stage in the manufacturing process where a capping layer 234 is applied over the sacrificial layer 230, the material 232, and the dislodged particles 222. In embodiments, the capping layer 234 may be a dielectric material, and may include materials like silicon dioxide and/or silicon nitride. In some embodiments, the capping layer 234 may be used to form the material 232 as described above with respect to FIG. 2D. The material used for capping layer 234 may be based on, among other things, the material to be deposited on top of it, such as subsequent layer 237 of FIG. 2H, to ensure good adhesion.

FIG. 2G shows a cross section side view of a stage in the manufacturing process where a portion of the capping layer 234, the dislodged particles 222, and the sacrificial layer 230 of FIG. 2F have been removed. In embodiments, a chemical mechanical polish (CMP) process may be used to remove the portion of the capping layer 234, the dislodged particles 222, and the sacrificial layer 230 of FIG. 2F to expose the surface of the third layer 214. In embodiments, this may also be accomplished using different etch strategies, or a combination of etch and CMP. A volume of capping material 235, which may be similar to capping layer 234 of FIG. 2E, may be directly above the material 232. Capping material 235 may partially overlap or completely overlap the material 232, and may cover the material 232 along a transverse direction of the material 232. In embodiments, the capping material 235 adjacent to the material 232.

FIG. 2H shows a cross section side view of a stage in the manufacturing process where the wafer portion 204 is returned to the manufacturing line and a subsequent layer 237 of the manufacturing process is placed upon the third layer 214 as wafer processing continues.

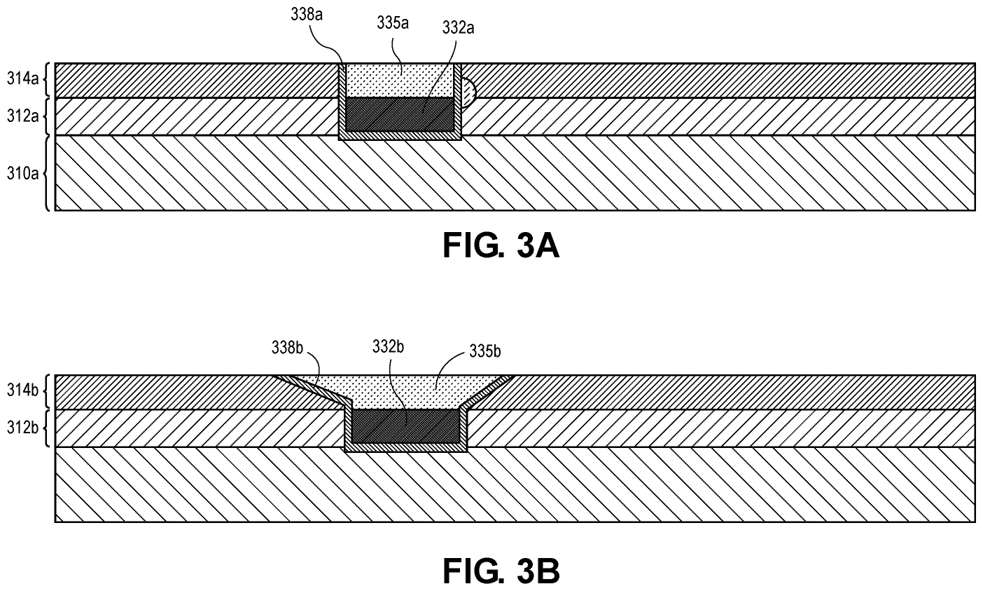

FIGS. 3A-3B show cross section views of alternative stages in a manufacturing process for checking for defects within a wafer, in accordance with various embodiments. FIG. 3A, which may be similar to the manufacturing stage of FIG. 2F, includes a first layer 310a, a second layer 312a, and a third layer 314a, capping material 335a, and material 332a which may be similar to first layer 210, second layer 212, third layer 214, capping material 235, and material 232 of FIG. 2F.

In this embodiment, a liner 338a physically separates the capping material 335a and the material 332a from the first layer 310a, the second layer 312a, and the third layer 314a. In embodiments, the liner may be used to facilitate adhesion between adjacent materials, or may be used to prevent diffusion between adjacent materials. In embodiments, the liner material may be selected based on the properties of the capping material 335a, the material 332a, the first layer 310a, the second layer 312a the third layer 314a, and may include material like titanium nitride. In embodiments, the liner 338a may be placed subsequent to the formation of the cavity, which may be similar to cavity 220 of FIG. 2C.

FIG. 3B, which may be similar to the manufacturing stage of FIG. 3A, shows capping material 335b, material 332b, and liner 338b, which may be similar to capping material 335a, material 332a, and liner 338a of FIG. 3A. In this embodiment, the liner 338b does not extend directly vertically up between second layer 312b and third layer 314b, but rather goes up at an angle, resulting in a wider capping material 335b forming a funnel shape, in comparison to the capping material 335a of FIG. 3A that is narrower. In embodiments, this may be the result of the creation of a funnel shape of the cavity, such as cavity 220 of FIG. 2C, before the liner 338b is applied, in order to facilitate subsequent placement of the material 332b and the capping material 335b.

In embodiments, a composition for the capping material 335b, the liner 338b, and the material 332b may be chosen to be chemically inactive to any chemicals that may be used in downstream manufacturing process stages for wafers that might be subtractive in nature at a level below the top surface of third layer 314b. In some embodiments, the capping material 335b, material 332b, and/or liner 338b may include the same material or may include different materials.

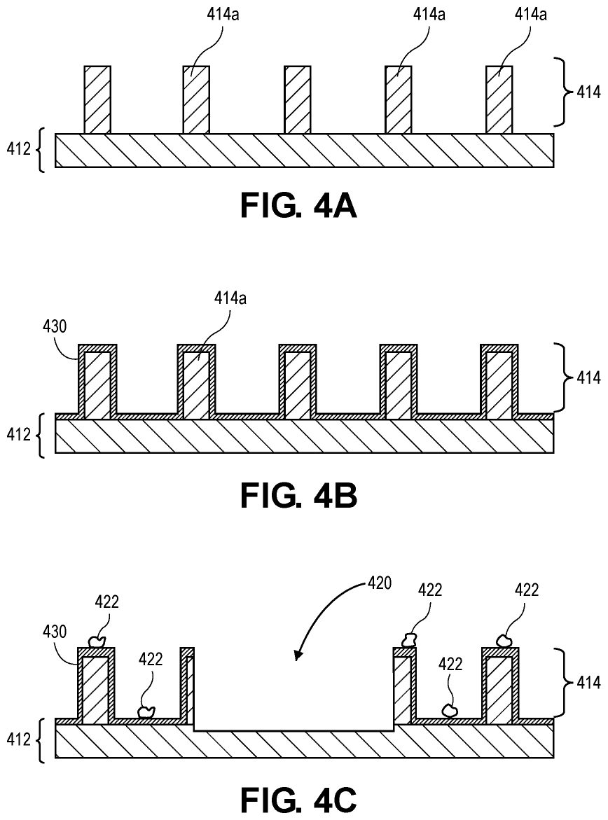

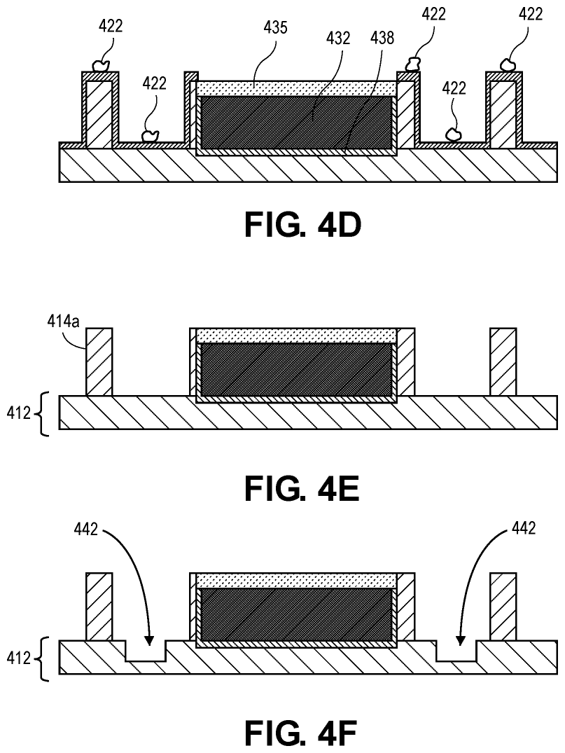

FIGS. 4A-4F show cross section side views of stages in a manufacturing process for that could be used to analyze a region of interest using a conformal sacrificial layer, in accordance with various embodiments. FIG. 4A shows a cross section side view of a stage in the manufacturing process where a first layer 412, which may be similar to second layer 212 of FIG. 2A, may have a second layer 414, which may be similar to third layer 214 of FIG. 2A, on the first layer 412. The second layer 414 includes a plurality of structures 414a. In embodiments, the structures 414a may include fins, trench side walls, and could be of uniform or un-uniform height.

FIG. 4B shows a cross section side view of a stage in the manufacturing process where a conformal sacrificial layer 430, which may be similar to sacrificial layer 230 of FIG. 2B, is applied to the first layer 412, and around the plurality of structures 414a.

FIG. 4C shows a cross section side view of a stage in the manufacturing process where a cavity 420 is formed into a portion of the plurality of structures 414a, and into a portion of the first layer 412. In embodiments, dislodged particles 422, which may be similar to dislodged particles 222 of FIG. 2D, may be on the sacrificial layer 430 as a result of the formation of cavity 420. In embodiments, after the cavity 420 is formed, cross-sectional analysis, as described respect to FIG. 1 above, may be performed.

FIG. 4D shows a cross section side view of a stage in the manufacturing process where the cavity 420 of FIG. 4C is first coated with the liner 438, which may be similar to liner 338a of FIG. 3A or liner 338b of FIG. 3B. Subsequently, a material 432, which may be similar to material 232 of FIG. 2D, may be placed within a portion of the cavity 420 of FIG. 4C, with the liner 438 physically separating material 432 from the first layer 412 and from the plurality of structures 414a. In addition, a capping layer 435, which may be similar to capping material 235 of FIG. 2F, may be placed on the material 432.

FIG. 4E shows a cross section side view of a stage in the manufacturing process where the sacrificial layer 430 is removed along with the dislodged particles 422. In embodiments, the sacrificial layer 430 and the dislodged particles 422 may be removed using, for example, wet and/or dry etch techniques. In embodiments, this will expose the first layer 412 and the remaining structures 414a for further processing on the manufacturing line.

FIG. 4F shows a cross section side view of the stage in the manufacturing process where cutouts 442 are etched into the first layer 412 below a level of the cavity 420 of FIG. 4C. In embodiments, a composition for the capping layer 435 and/or a composition for the material 432 may be chosen so that they do not interact with the chemicals used during etching used to create the cutouts 442. In embodiments, the cutouts 442 may be part of a subtractive stage in manufacturing that may be followed by a variety of depositions such as metal and/or a dielectric (not shown) during a subsequent additive stage.

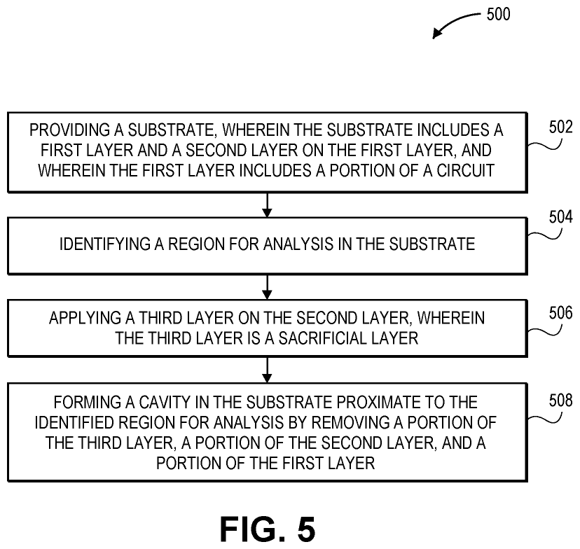

FIG. 5 illustrates a process for performing a cross-section analysis of a substrate, in accordance with various embodiments. Process 500 may be performed by using the systems, apparatus, techniques, and processes described herein, and in particular with respect to FIGS. 1-4F.

At block 502, the process may include providing a substrate, wherein the substrate includes a first layer and a second layer on the first layer and wherein the first layer includes portions of a circuit. In embodiments, the substrate may be similar to wafer portion 104a of FIG. 1. In embodiments, the first layer and the second layer may be similar to first layer 110 and second layer 112 of FIG. 1.

At block 504, the process may further include identifying a location of a region of interest in the substrate. In embodiments, the location of the region of interest in the substrate may be similar to the indication of a possible defect 106 of FIG. 1.

At block 506, the process may further include applying a third layer on the second layer, wherein the third layer is a sacrificial layer. In embodiments, the third layer may be similar to third layer 430 of FIG. 4B.

At block 508, the process may further include forming a cavity in the substrate proximate to the identified location by removing a portion of the third layer, a portion of the second layer, and a portion of the first layer. In embodiments, the cavity may be similar to cavity 120 of FIG. 1.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

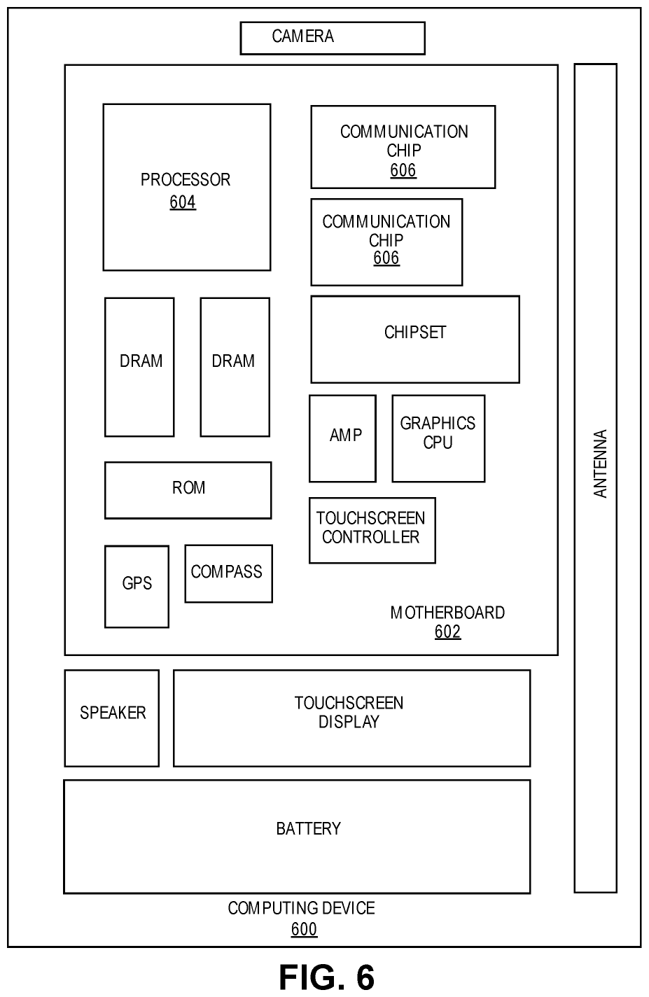

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip includes one or more devices, such as MOS-FET transistors built in accordance with implementations of the invention.

In further implementations, another component housed within the computing device 600 may contain an integrated circuit die that includes one or more devices, such as MOS-FET transistors built in accordance with implementations of the invention.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

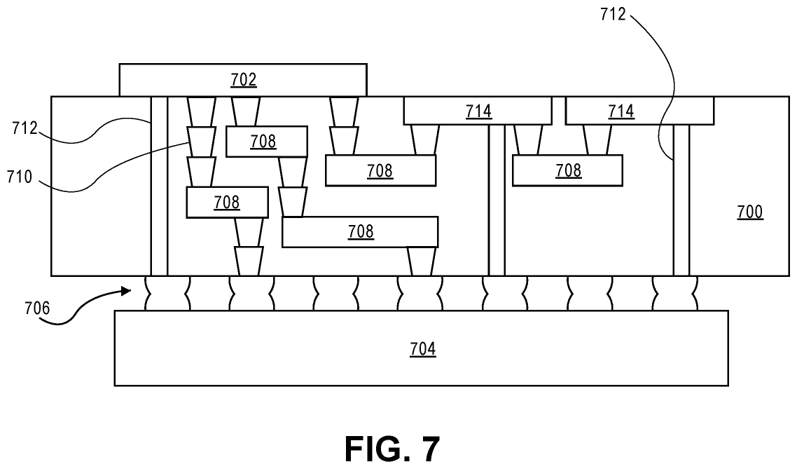

FIG. 7 illustrates an interposer 700 that includes one or more embodiments of the invention. The interposer 700 is an intervening substrate used to bridge a first substrate 702 to a second substrate 704. The first substrate 702 may be, for instance, an integrated circuit die. The second substrate 704 may be, for instance, a memory module, a computer motherboard, or another integrated circuit die. Generally, the purpose of an interposer 700 is to spread a connection to a wider pitch or to reroute a connection to a different connection. For example, an interposer 700 may couple an integrated circuit die to a ball grid array (BGA) 706 that can subsequently be coupled to the second substrate 704. In some embodiments, the first and second substrates 702/704 are attached to opposing sides of the interposer 700. In other embodiments, the first and second substrates 702/704 are attached to the same side of the interposer 700. And in further embodiments, three or more substrates are interconnected by way of the interposer 700.

The interposer 700 may be formed of an epoxy resin, a fiberglass-reinforced epoxy resin, a ceramic material, or a polymer material such as polyimide. In further implementations, the interposer 700 may be formed of alternate rigid or flexible materials that may include the same materials described above for use in a semiconductor substrate, such as silicon, germanium, and other group III-V and group IV materials.

The interposer 700 may include metal interconnects 708 and vias 710, including but not limited to through-silicon vias (TSVs) 712. The interposer 700 may further include embedded devices 714, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 700. In accordance with embodiments of the invention, apparatuses or processes disclosed herein may be used in the fabrication of interposer 700.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is a substrate comprising: a first layer; a first volume of a first material in the first layer, wherein the first volume of the first material in the first layer extends from a first side of the first layer to a second side of the first layer opposite the first side of the first layer; a second layer on the first side of the first layer; a second volume of a second material in the second layer, wherein the second volume of the second material extends from a first side of the second layer to a second side of the second layer opposite the first side of the second layer; and wherein the second volume of the second material in the second layer is adjacent to the first volume of the first material in the first layer.

Example 2 may include the substrate of example 1, or of any other example or embodiment described herein, wherein the second volume of the second material completely overlaps the first volume of the first material in the first layer.

Example 3 may include the substrate of example 1, or of any other example or embodiment described herein, wherein a bottom surface of the first volume of the first material in the first layer proximate to the second side of the first layer is not coplanar with the second side of the first layer.

Example 4 may include the substrate of example 1, or of any other example or embodiment described herein, wherein the first material includes a selected one or more of: an epoxy material, a liquid mold material, or dielectric material; and wherein the second material includes a selected one or more of: a dielectric or an epoxy.

Example 5 may include the substrate of example 1, or of any other example or embodiment described herein, wherein the first material and the second material are a same material.

Example 6 may include the substrate of example 1, or of any other example or embodiment described herein, further comprising a liner that physically separates the first volume of the first material from the first layer and physically separates the second volume of the second material from the second layer.

Example 7 may include the substrate of example 6, or of any other example or embodiment described herein, wherein the liner includes a selected one or more of: a dielectric material, an epoxy material, or liquid mold material.

Example 8 may include the substrate of example 1, or of any other example or embodiment described herein, wherein a side of the first volume of the first material in the first layer that extends from the first side of the first layer to the second side of the second layer is substantially perpendicular to the first side of the first layer.

Example 9 may include the substrate of example 1, or of any other example or embodiment described herein, wherein the first layer includes portions of a circuit.

Example 10 may include the substrate of example 1, or of any other example or embodiment described herein, wherein the substrate is a portion of a selected one or more of: one or more bonded wafers, a wafer that includes one or more individual dies, a package substrate, or a packaged unit.

Example 11 is a wafer comprising: a first layer with a first side and a second side opposite the first side; a second layer with a first side and a second side opposite the first side, wherein the second side of the second layer is on the first side of the first layer; a third layer with a first side and a second side opposite the first side, wherein the second side of the third layer is on the first side of the second layer; and a cavity extending from the first side of the third layer to the second side of the first layer, wherein a side of the cavity in the first layer is substantially perpendicular to the first side of the first layer.

Example 12 may include the wafer of example 11, or of any other example or embodiment described herein, wherein a bottom of the cavity proximate to the second side of the first layer is not coplanar with the second side of the first layer.

Example 13 may include the wafer of example 11, or of any other example or embodiment described herein, further comprising a volume of epoxy in the cavity, the volume of epoxy extending from the second side of the first layer to the first side of the first layer.

Example 14 may include the wafer of example 13, or of any other example or embodiment described herein, further comprising a dielectric on the volume of epoxy.

Example 15 may include the wafer of example 14, or of any other example or embodiment described herein, wherein the dielectric completely overlaps the volume of epoxy.

Example 16 is a process comprising: providing a substrate, wherein the substrate includes a first layer and a second layer on the first layer, and wherein the first layer includes a portion of a circuit; identifying a region for analysis in the substrate; applying a third layer on the second layer, wherein the third layer is a sacrificial layer; and forming a cavity in the substrate proximate to the identified region for analysis by removing a portion of the third layer, a portion of the second layer, and a portion of the first layer.

Example 17 includes the process of example 16, or of any other example or embodiment described herein, wherein removing the portion of the third layer, the portion of the second layer, and the portion of the first layer further includes removing the portion of the third layer, the portion of the second layer, and the portion of the first layer using a selected one or more of: a focused ion beam or chemical etching.

Example 18 includes the process of example 17, or of any other example or embodiment described herein, further comprising analyzing the removed portion of the third layer, the removed portion of the second layer, and/or the removed portion of the first layer.

Example 19 includes the process of example 16, or of any other example or embodiment described herein, further comprising: inserting an epoxy into a portion of the cavity proximate to the first layer; and applying a fourth layer on the substrate, wherein the fourth layer is on the third layer and on the epoxy, and wherein the fourth layer includes a dielectric.

Example 20 includes the process of example 19, or of any other example or embodiment described herein, further comprising removing the third layer and at least a portion of the fourth layer.

What is claimed is:

1. A substrate comprising:
a first layer;
a first volume of a first material in the first layer, wherein the first volume of the first material in the first layer extends from a first side of the first layer to a second side of the first layer opposite the first side of the first layer;
a second layer on the first side of the first layer;
a second volume of a second material in the second layer, wherein the second volume of the second material extends from a first side of the second layer to a second side of the second layer opposite the first side of the second layer; and
wherein the second volume of the second material in the second layer is adjacent to the first volume of the first material in the first layer.

2. The substrate of claim 1, wherein the second volume of the second material completely overlaps the first volume of the first material in the first layer.

3. The substrate of claim 1, wherein a bottom surface of the first volume of the first material in the first layer proximate to the second side of the first layer is not coplanar with the second side of the first layer.

4. The substrate of claim 1, wherein the first material includes a selected one or more of: an epoxy material, a liquid mold material, or dielectric material; and
wherein the second material includes a selected one or more of: a dielectric or an epoxy.

5. The substrate of claim 1, wherein the first material and the second material are a same material.

6. The substrate of claim 1, further comprising a liner that physically separates the first volume of the first material from the first layer and physically separates the second volume of the second material from the second layer.

7. The substrate of claim 6, wherein the liner includes a selected one or more of: a dielectric material, an epoxy material, or liquid mold material.

8. The substrate of claim 1, wherein a side of the first volume of the first material in the first layer that extends from the first side of the first layer to the second side of the second layer is substantially perpendicular to the first side of the first layer.

9. The substrate of claim 1, wherein the first layer includes portions of a circuit.

10. The substrate of claim 1, wherein the substrate is a portion of a selected one or more of:
one or more bonded wafers, a wafer that includes one or more individual dies, a package substrate, or a packaged unit.

11. A wafer comprising:
a first layer with a first side and a second side opposite the first side;
a second layer with a first side and a second side opposite the first side, wherein the second side of the second layer is on the first side of the first layer;
a third layer with a first side and a second side opposite the first side, wherein the second side of the third layer is on the first side of the second layer; and
a cavity extending from the first side of the third layer to the second side of the first layer, wherein a side of the cavity in the first layer is substantially perpendicular to the first side of the first layer.

12. The wafer of claim 11, wherein a bottom of the cavity proximate to the second side of the first layer is not coplanar with the second side of the first layer.

13. The wafer of claim 11, further comprising a volume of epoxy in the cavity, the volume of epoxy extending from the second side of the first layer to the first side of the first layer.

14. The wafer of claim 13, further comprising a dielectric on the volume of epoxy.

15. The wafer of claim 14, wherein the dielectric completely overlaps the volume of epoxy.

16. A process comprising:
providing a substrate, wherein the substrate includes a first layer and a second layer on the first layer, and wherein the first layer includes a portion of a circuit;
identifying a region for analysis in the substrate;
applying a third layer on the second layer, wherein the third layer is a sacrificial layer; and
forming a cavity in the substrate proximate to the identified region for analysis by removing a portion of the third layer, a portion of the second layer, and a portion of the first layer.

17. The process of claim 16, wherein removing the portion of the third layer, the portion of the second layer, and the portion of the first layer further includes removing the portion of the third layer, the portion of the second layer, and the portion of the first layer using a selected one or more of: a focused ion beam or chemical etching.

18. The process of claim 17, further comprising analyzing the removed portion of the third layer, the removed portion of the second layer, and/or the removed portion of the first layer.

19. The process of claim 16, further comprising:
inserting an epoxy into a portion of the cavity proximate to the first layer; and
applying a fourth layer on the substrate, wherein the fourth layer is on the third layer and on the epoxy, and wherein the fourth layer includes a dielectric.

20. The process of claim 19, further comprising removing the third layer and at least a portion of the fourth layer.
